(19) United States
(12) Patent Application Publication
(10) Pub. No.: US 2013/0170111 A1
(43) Pub. Date: Jul. 4, 2013

(54) PANEL

(71) Applicants: PING LI, Shenzhen City (CN); BAO-GANG ZHAO, Shenzhen City (CN); XUE-FENG WAN, Shenzhen City (CN)

(72) Inventors: PING LI, Shenzhen City (CN); BAO-GANG ZHAO, Shenzhen City (CN); XUE-FENG WAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/517,688

(22) Filed: Jun. 14, 2012

(30) Foreign Application Priority Data
Dec. 28, 2011 (CN) 201110447135.9

(51) Int. Cl. H05K 7/00

(52) U.S. Cl. 361/679.01

(57) ABSTRACT

A panel includes a main body, an assisting member, and an arm. The main body defines a receiving groove. The assisting member is located in the receiving groove. The arm protrudes from the assisting member. The assisting member is located between the main body and the arm, and one end of the assisting member from which the arm protruding is considered as a molding surface when demolded.

### BACKGROUND

1. Technical Field

The present disclosure relates to panels, and particularly to a panel for an electronic device.

2. Description of Related Art

Electronic devices commonly include a casing, and a panel detachably engaging with the casing. The panel includes a receiving groove, and an arm defining a hole. A protrusion or a tab of the casing is inserted in the hole of the arm so as to fasten the panel to the casing. However, in the typical panel, the arm extends from the bottom of the receiving groove to the exterior of the receiving groove. The bottom of the receiving groove which the arm extends from is determined as the molding surface when the panel is demolded. The mold moves out of the panel from the molding surface through the receiving groove during demolding, so that the movement stroke of the mold is long. Therefore, it is difficult to obtain a typical panel in molding.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of a panel.

FIG. 2 is enlarged view of a circled portion II of FIG. 1.

### DETAILED DESCRIPTION

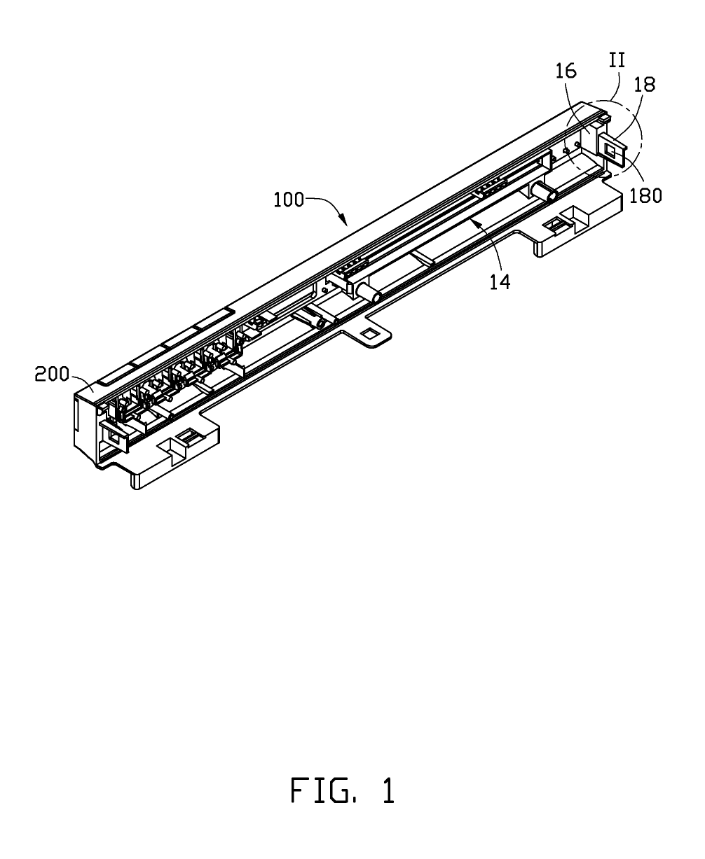

Referring to FIG. 1, a panel 100 includes main body 200, a receiving groove 14 defined in the main body 200, two assisting members 16 located in the receiving groove 14, and an arm 18 protruding from the assisting member 16.

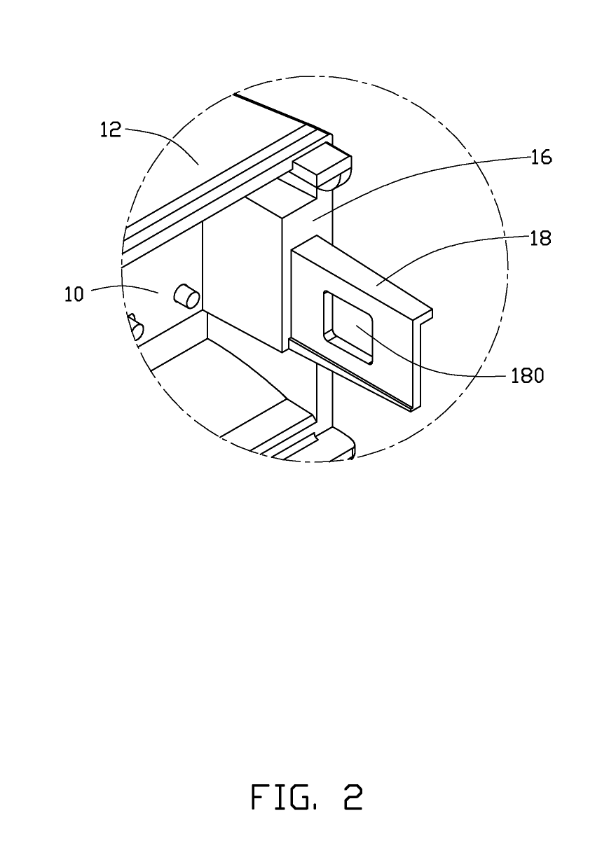

The main body 200 includes a rectangular base 10, and a sidewalls 12 protruding from the edge of the rectangular base 10 (see FIG. 2). The base 10 and the sidewalls 12 cooperatively form the receiving groove 14. The base 10 functions as the bottom of the receiving groove 14.

Referring to FIG. 2, the two assisting members 16 are located in two ends of the receiving groove 14. The assisting members 16 are rectangular blocks, which are integrally formed with the base 10 and the sidewall 12. The end of the assisting member 16 away from the base 10 is a plane, and is coplanar with the end of the sidewall 12 away from the base 10.

Each arm 18 is located at the exterior of the receiving groove 14, extending from the end of the assisting member 16 away from base 10. The cross-section of the arm 18 is L shaped. The arm 18 defines a hole 180.

As described above, the arm 18 protruding from the end of the assisting member 16, and the end of the assisting member 18 is determined as the molding surface when demolded. Therefore, a mold for the panel 100 moves out of the panel 100 does not need to move through the receiving groove 14 when demolded. Therefore, it is easy to obtain the panel 100 in molding.

It is to be understood, however, that even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A panel, comprising:
a main body defining a receiving groove;
an assisting member located in the receiving groove, and
an arm protruding from the assisting member;
wherein one end of the assisting member from which the arm protrudes is considered as a molding surface when demolded.

2. The panel of claim 1, wherein the end of the assisting member from which the arm protrudes is coplanar with the end of the main body.

3. The panel of claim 1, wherein the end of the assisting member is a flat plane.

4. The panel of claim 1, wherein the arm has an L shape cross-section.

5. The panel of claim 1, wherein the arm defines a hole.

6. The panel of claim 1, wherein the main body comprises a base, and a sidewall protruding from edge of the base, the sidewall and the base cooperatively define the receiving groove, the base is the bottom of the receiving groove.

7. The panel of claim 6, wherein the assisting member is integral with the base.

8. The panel of claim 6, wherein the assisting member is integral with the sidewall.

9. The panel of claim 8, wherein the end of the assisting member from which the arm protrudes is coplanar with the end of the sidewall away from the base.
